(19) United States
(12) Patent Application Publication
(10) Pub. No.: US 2026/0314269 A1
(43) Pub. Date: Oct. 8, 2026

(54) METHOD AND APPARATUS WITH SUPERCONDUCTING QUANTUM CHIP

(71) Applicant: Samsung Electronics Co., Ltd., Suwon-si (KR)

(72) Inventor: Daeyun KIM, Suwon-si (KR)

(73) Assignee: Samsung Electronics Co., Ltd., Suwon-si (KR)

(21) Appl. No.: 19/057,142

(22) Filed: Feb. 19, 2025

(30) Foreign Application Priority Data
Oct. 16, 2024 (KR) 10-2024-0141448

(51) Int. Cl. H10N 60/81; H03K 17/92; H10N 60/80; G06N 10/40

(52) U.S. Cl. CPC H10N 60/815; H03K 17/92; H10N 60/805; G06N 10/40

(57) ABSTRACT

A superconducting quantum chip including a first chip including a superconducting quantum device having a controllable resonant frequency, a second chip bonded to the first chip with a gap defined between the first chip and the second chip, and a ferromagnetic device provided on the second chip, the ferromagnetic device being configured to apply a magnetic field to the superconducting quantum device to control a resonant frequency of the superconducting quantum device.

### CROSS-REFERENCE TO RELATED APPLICATION

This application is based on and claims priority under 35 U.S.C. §119 to Korean Patent Application No. 10-2024-0141448, filed on Oct. 16, 2024, in the Korean Intellectual Property Office, the disclosure of which is incorporated by reference herein in its entirety.

### BACKGROUND

### 1. FIELD

The disclosure relates to a method and apparatus with a superconducting quantum computer.

### DESCRIPTION OF THE RELATED ART

Since the concept of quantum computers was first proposed in the late 20th century, much research and development has been invested into developing practical quantum computers. Superconducting quantum computers utilize the quantum properties of superconductors and are considered the most promising approach among current development efforts in quantum computers.

Typically, as a number of qubits in a quantum computer increases, the more powerful that superconducting quantum computer may become. For example, a superconducting quantum computer may perform calculations in parallel by superposing 2ⁿ patterns with n qubits. However, as the number of qubits in a quantum computer system increases, the complexity of that quantum computer system also increases. Accordingly, there is a desire to achieve efficient methods and devices in the construction of superconducting quantum computers.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a superconducting quantum chip including a first chip including a superconducting quantum device having a controllable resonant frequency, a second chip bonded to the first chip with a gap defined between the first chip and the second chip, and a ferromagnetic device provided on the second chip, the ferromagnetic device being configured to apply a magnetic field to the superconducting quantum device to control a resonant frequency of the superconducting quantum device.

The superconducting quantum device may be arranged on a first surface of the first chip, the ferromagnetic device may be arranged on a second surface of the second chip, and the first surface and the second surface may be configured to face each other.

The first chip may include a first substrate on which the superconducting quantum device is arranged and the first substrate may include a magnetic shielding material.

The second chip may include a second substrate on which the ferromagnetic device is arranged and the second substrate may include a magnetic shielding material.

The superconducting quantum chip may include an interconnect component configured to physically connect the first chip and the second chip to each to form the gap between the first chip and the second chip, and the interconnect component may include a superconducting material.

The ferromagnetic device may include a magnetic domain wall, the superconducting quantum device may be configured to have a resonant frequency that changes with a position of the magnetic domain wall, and the position of the magnetic domain wall may be determined based on a current flowing through the ferromagnetic device.

The second chip may be a wire arranged adjacent to the ferromagnetic device,

the superconducting quantum device may be configured to have a resonant frequency that changes depending on a magnetization direction of a ferromagnetic device, and the magnetization direction may be determined based on a current flowing through the wire.

The second chip may include a voltage gate connected to the ferromagnetic device, the superconducting quantum device may be configured to have a resonant frequency that changes depending on a magnetization direction of the ferromagnetic device, and the magnetization direction is determined based on a voltage applied through the voltage gate.

The second chip may include a magnetization control circuit configured to control a magnetization of the ferromagnetic device.

The superconducting quantum chip may include an intermediate layer provided between the first chip and the second chip, the intermediate layer including a magnetic shielding material, and the intermediate layer may be bonded to the first chip and the second chip to form a first gap with respect to the first chip and a second gap with respect to the second chip.

The intermediate layer may include a first region in which a magnetic field generated by the ferromagnetic device is not blocked and a second region in which the magnetic field generated by the ferromagnetic device is blocked.

The first region of the intermediate layer may not include the magnetic shielding material and the second region of the intermediate layer may include the magnetic shielding material.

The intermediate layer may be an insulating layer, the insulating layer may not be coated with the magnetic shielding material in the first region, and the insulating layer may be coated with the magnetic shielding material in the second region.

The intermediate layer may include a magnetic shielding layer, the magnetic shielding layer having a hole defined therein, the first region being defined by the hole, and the second region including a remaining region of the magnetic shielding layer.

The superconducting quantum device may include a loop formed by a first superconducting layer, a second superconducting layer, a first Josephson junction, and a second Josephson junction, and the first region faces the loop.

A width of the first region may be less than 100 μm.

The superconducting quantum chip may include a first interconnect component configured to physically connect the first chip to the intermediate layer such that the first gap is formed between the first chip and the intermediate layer and a second interconnect component configured to physically connect the second chip to the intermediate layer such that the second gap is formed between the second chip and the intermediate layer.

In a general aspect, here is provided a method including controlling a magnetic field of a ferromagnetic device of a second chip of a superconducting quantum chip, the superconducting quantum chip including a first chip including a superconducting quantum device, the second chip, the second chip being bonded to the first chip and having a gap defined between the first chip and the second chip, and a ferromagnetic device, applying the controlled magnetic field to the superconducting quantum device of the first chip, and controlling a resonant frequency of the superconducting quantum device of the first chip based on the applied magnetic field.

In a general aspect, here is provided an electronic device including a ferromagnetic device formed on a second chip, the second chip being bonded to a first chip, the ferromagnetic device being configured to apply a magnetic field to a superconducting quantum device of the first chip to control a resonant frequency of the superconducting quantum device, a processor configured to execute instructions, and a memory storing the instructions, and an execution of the instructions configures the processor to control a magnetization of the ferromagnetic device by applying a current pulse to the ferromagnetic device to change a location of a magnetic domain wall within the ferromagnetic device.

The superconducting quantum device may include first and second Josephson junctions and first and second superconducting layers, the first and second superconducting layers and the first and second Josephson junctions being configured to form a loop, and the location of magnetic domain wall may change an amount of magnetic flux passing through the loop to control the resonant frequency of the superconducting quantum device.

### BRIEF DESCRIPTION OF THE DRAWINGS

FIGS. 1A and 1B illustrate example superconducting quantum chips according to one or more embodiments.

FIG. 2 illustrate an example superconducting quantum chip according to one or more embodiments.

FIG. 3 illustrate an example superconducting quantum chip according to one or more embodiments.

FIGS. 4A-4C illustrate an example superconducting quantum chip according to one or more embodiments.

FIGS. 5A-5E illustrate an example superconducting quantum chip according to one or more embodiments.

FIGS. 6A-6C illustrate an example superconducting quantum chip according to one or more embodiments.

FIG. 7A illustrates an example interconnect component according to one or more embodiments.

FIG. 7B illustrates an example interconnect component according to one or more embodiments.

FIGS. 8A and 8B illustrate an example superconducting quantum chip according to one or more embodiments.

FIGS. 9A and 9B illustrate an example intermediate layer according to one or more embodiments.

FIG. 10 illustrate an example method of operating a superconducting quantum chip according to one or more embodiments.

FIG. 11 illustrates an example electronic device according to one or more embodiments.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as "first," "second," and "third", or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles "a," "an," and "the" are intended to include the plural forms as well, unless the context clearly indicates otherwise. As non-limiting examples, terms "comprise" or "comprises," "include" or "includes," and "have" or "has" specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms "comprise" or "comprises," "include" or "includes," and "have" or "has" specify the presence of stated features, numbers, operations, members, elements, and/or combinations thereof, other embodiments may exist where one or more of the stated features, numbers, operations, members, elements, and/or combinations thereof are not present.

As used herein, the term "and/or" includes any one and any combination of any two or more of the associated listed items. The phrases "at least one of A, B, and C", "at least one of A, B, or C”, and the like are intended to have disjunctive meanings, and these phrases "at least one of A, B, and C", "at least one of A, B, or C", and the like also include examples where there may be one or more of each of A, B, and/or C (e.g., any combination of one or more of each of A, B, and C), unless the corresponding description and embodiment necessitates such listings (e.g., "at least one of A, B, and C") to be interpreted to have a conjunctive meaning.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term "may" herein with respect to an example or embodiment, e.g., as to what an example or embodiment may include or implement, means that at least one example or embodiment exists where such a feature is included or implemented, while all examples are not limited thereto.

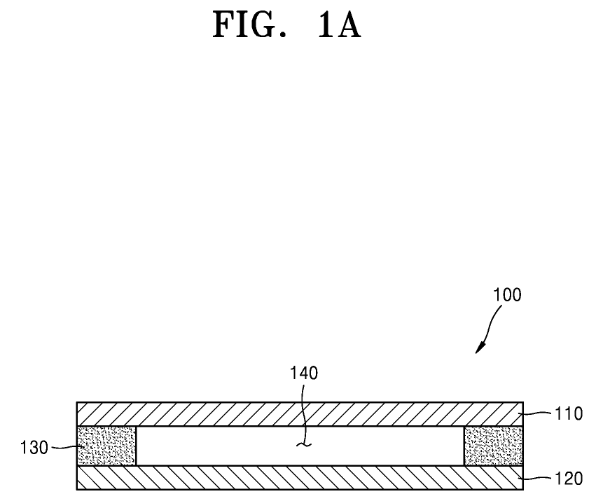

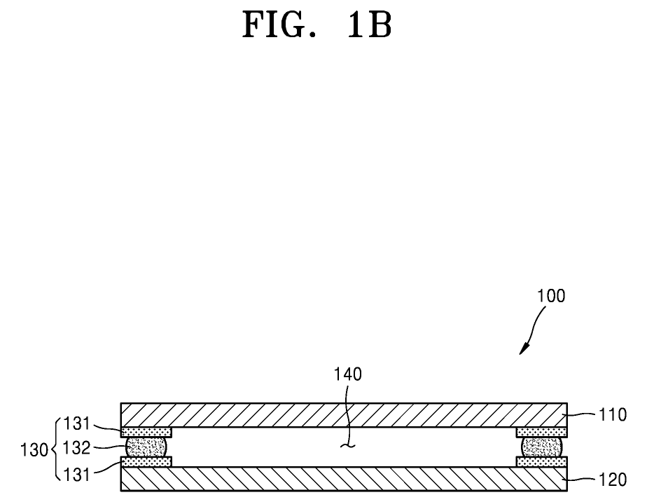

FIGS. 1A and 1B illustrate example superconducting quantum chips according to one or more embodiments.

Referring to FIG. 1A, in a non-limiting example, a superconducting quantum chip 100 may include a first chip 110 and a second chip 120. The first chip 110 may include at least one superconducting quantum device. The second chip 120 may include at least one ferromagnetic device.

The first chip 110 may be bonded to the second chip 120 with a gap 140 therebetween. In an example, the first chip 110 and the second chip 120 may be physically connected to each other by an interconnect component 130.

In an example, the superconducting quantum device may be a device having quantum properties of superposition. For example, a superconducting quantum device may be a qubit. For example, the superconducting quantum device may be a device for controlling the coupling strength between qubits for quantum computation. For example, the superconducting quantum device may be a qubit coupler.

The ferromagnetic device may be configured to apply a magnetic field to the superconducting quantum device. The ferromagnetic device may include a ferromagnetic material. The ferromagnetic material may include, but is not limited to, Co, CoFeB, cobalt-nickel (Co-Ni), cobalt-platinum (Co-Pt), gadolinium-cobalt (Gd-Co), or a metal compound containing rare earth atoms such as neodymium (Nd) or sabarium (Sm).

In an example, the ferromagnetic device may have a layered structure of a heavy metal layer and a ferromagnetic layer. In an example, the ferromagnetic device may have a layered structure of a heavy metal layer, a ferromagnetic layer, and an insulating layer. The heavy metal layer may include a heavy metal such as, but is not limited to, platinum (Pt), tantalum (Ta), palladium (Pd), tungsten (W), or ruthenium (Ru). The ferromagnetic layer may include a ferromagnetic material. The insulating layer may include an insulating material such as, but is not limited to, magnesium oxide (MgO), aluminum oxide (AlOx), or tantalum oxide (TaOx). For example, the ferromagnetic device may include, but is not limited to, at least one of Pt/Co/MgO, Pt/Co/AlOx, Pt/CoFeB/MgO, Pt/(Co-Ni), or Pt/(Co-Pt).

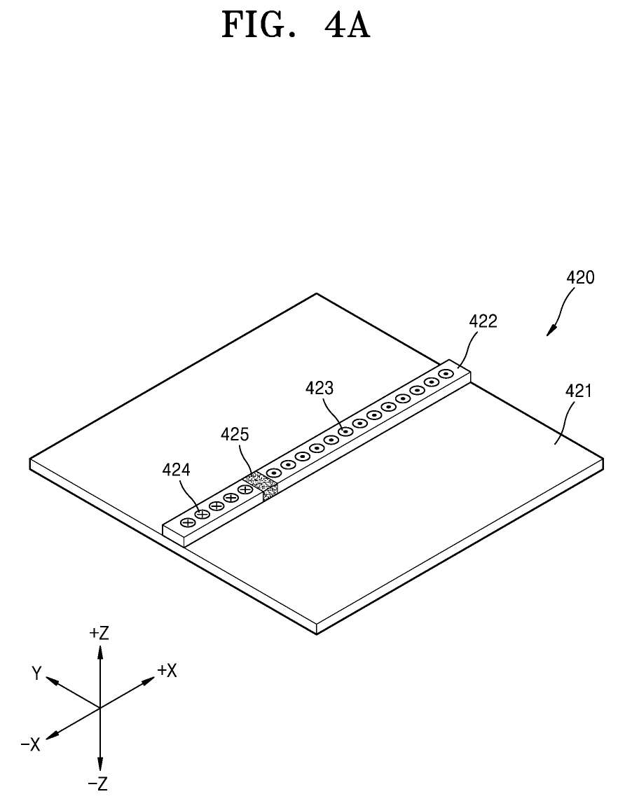

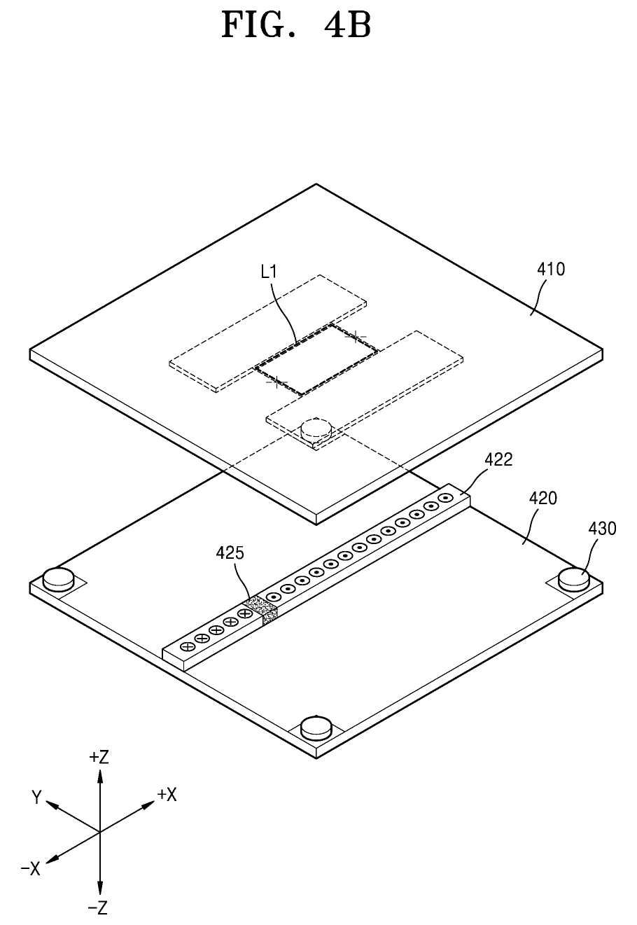

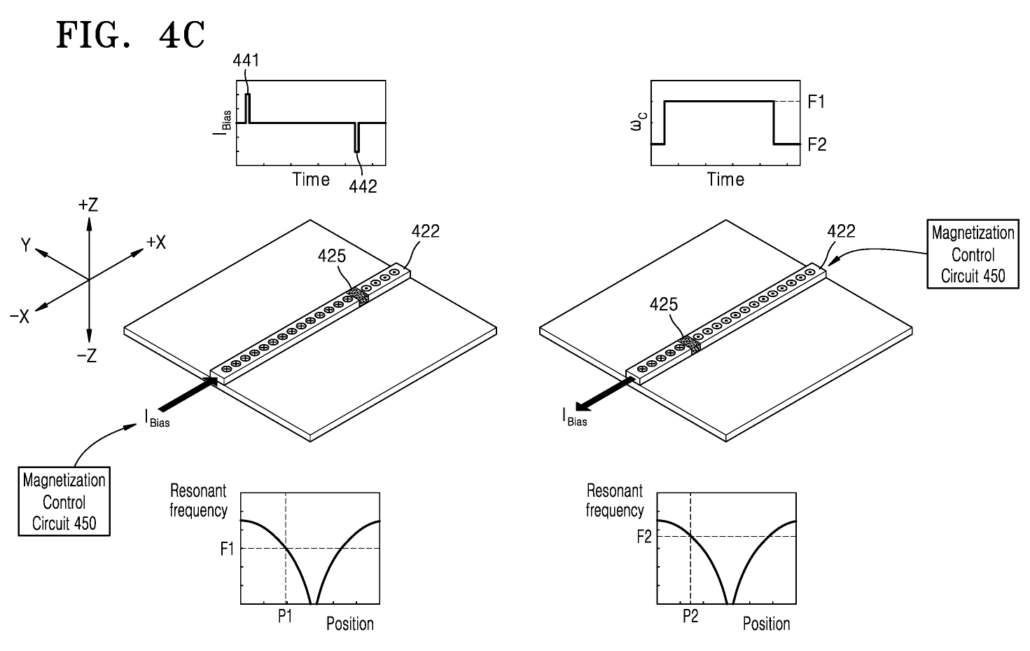

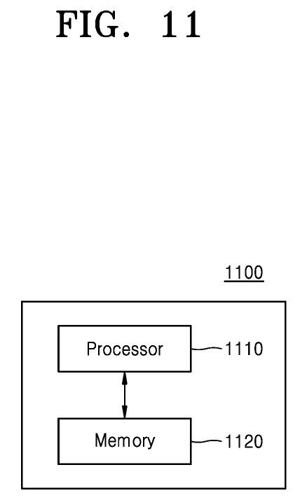

In an example, the superconducting quantum chip 100 may further include a magnetization control circuit (e.g., magnetization control circuit 450 of FIG. 4C and/or electronic device 1100 of FIG. 11) configured to control magnetization of the ferromagnetic device. The magnetization control circuit may control magnetization of a ferromagnetic device by applying a current or voltage to the ferromagnetic device.

In an example, the magnetization control circuit may be arranged in the second chip 120. The magnetization control circuit may be arranged in a same layer as the ferromagnetic device. Alternatively, the second chip 120 may have a layered structure, and the magnetization control circuit may be arranged in a different layer from the ferromagnetic device.

Based on a magnetic field of the ferromagnetic device, a resonant frequency of the superconducting quantum device may be controlled. In an example, the resonant frequency of the superconducting quantum device may be changed depending on a magnetization direction of the ferromagnetic device, i.e., depending on a direction of the magnetic field of the ferromagnetic device. In an example, the resonant frequency of the superconducting quantum device may be changed depending on a magnetic flux of the ferromagnetic device passing through the superconducting quantum device.

In an example, the interconnect component 130 may include a superconducting material. The superconducting material may include, but is not limited to, at least one of aluminum (Al), neodymium (Nb), indium (In), alpha-tantalum (α-Ta), titanium (Ti), lead (Pb), vanadium (V), or compounds thereof (e.g., NbN, NbTiN, TiN, or VN).

Referring to FIG. 1B, in an example, the interconnect component 130 may include a pad 131 and a bump 132. Likewise, the pad 131 and/or the bump 132 may include a superconducting material.

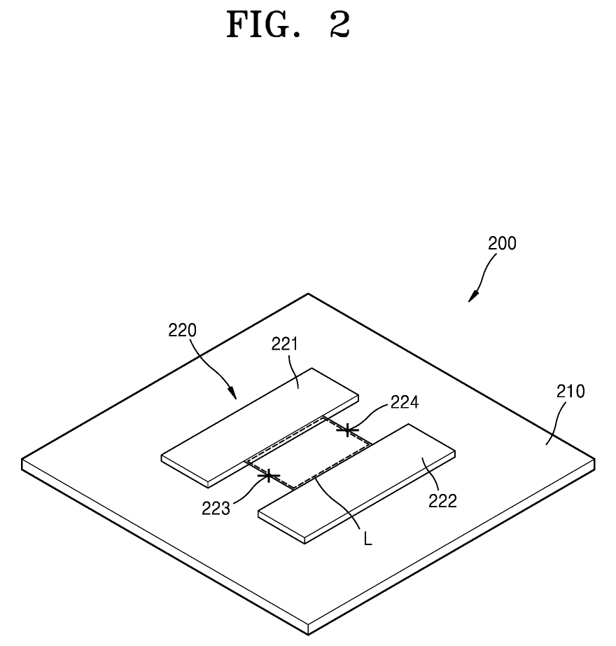

FIG. 2 illustrate an example superconducting quantum chip according to one or more embodiments.

Referring to FIG. 2, in a non-limiting example, a first chip 200 may include a substrate 210 and a superconducting quantum device 220. The superconducting quantum device 220 may include first and second superconducting layers 221 and 222 and first and second Josephson junctions 223 and 224.

The substrate 210 may be a silicon substrate. Alternatively, the substrate 210 may be a silicon on insulator (SOI) substrate, a sapphire substrate, or an insulating substrate including various other materials.

The first and second superconducting layers 221 and 222 may include a superconducting material. The first and second superconducting layers 221 and 222 may include a same superconducting material or different superconducting materials. The superconducting material may include, but is not limited to, at least one of aluminum (Al), neodymium (Nb), indium (In), alpha-tantalum (α-Ta), titanium (Ti), lead (Pb), vanadium (V), or compounds thereof (e.g., NbN, NbTiN, TiN, or VN).

The first and second Josephson junctions 223 and 224 may include a superconductor-weak link-superconductor. In an embodiment, a weak link may include, but is not limited to, an insulating material or a ferromagnetic material.

In an example, the first and second superconducting layers 221 and 222 and the first and second Josephson junctions 223 and 224 may form a loop L. A resonant frequency of the superconducting quantum device 220 may be determined based on a magnetic flux passing through the loop L.

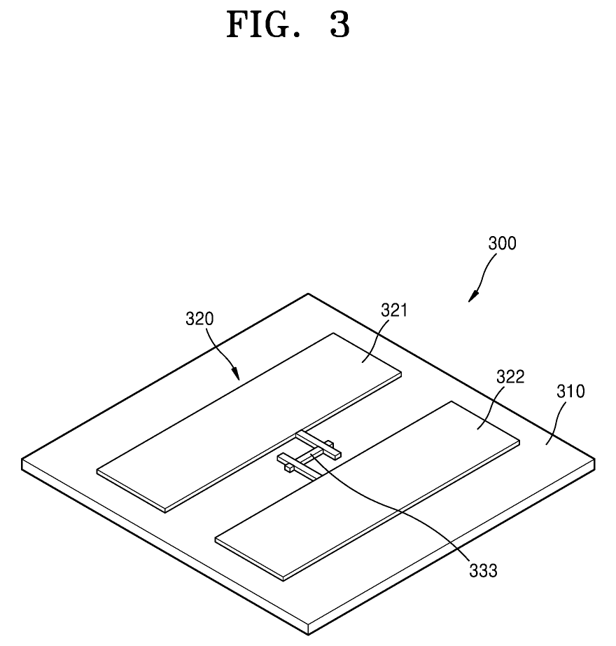

FIG. 3 illustrate an example superconducting quantum chip according to one or more embodiments.

The description of FIG. 2 may similarly apply to FIG. 3 and therefore similar descriptions between the two are omitted.

Referring to FIG. 3, in a non-limiting example, a first chip 300 may include a substrate 310 and a superconducting quantum device 320. The superconducting quantum device 320 may include a first super conducting layer 321 and a second superconducting layer 322 and a ferromagnetic link 333.

In an example, the first and second superconducting layers 321 and 322 may be coupled to each other by the ferromagnetic link 333. The first and second superconducting layers 321 and 322 and the ferromagnetic link 333 may form a Josephson junction. The ferromagnetic link 333 may correspond to a weak link of the Josephson junction.

The ferromagnetic link 333 may include a ferromagnetic material. In an example, the ferromagnetic link 333 may have a layered structure of a heavy metal layer, a ferromagnetic layer, and an insulating layer.

In an example, a resonant frequency of the superconducting quantum device 320 may vary depending on a location of a magnetic domain wall of the ferromagnetic link 333. A position of the magnetic domain wall of the ferromagnetic link 333 may be determined according to a magnetic field applied to the ferromagnetic link 333.

In an example, the resonant frequency of the superconducting quantum device 320 may be determined based on a magnetic skyrmion of the ferromagnetic link 333. The resonant frequency of the superconducting quantum device 320 may vary when a magnetic skyrmion is formed in the ferromagnetic link 333 and when the magnetic skyrmion is not formed.

FIGS. 4A-4C illustrate an example superconducting quantum chip according to one or more embodiments.

Referring to FIG. 4A, in a non-limiting example, a second chip 420 may include a substrate 421 and a ferromagnetic device 422.

The substrate 421 may be a silicon substrate. Alternatively, the substrate 421 may be an SOI substrate, a sapphire substrate, or an insulating substrate including various other materials.

In an example, a magnetization of the ferromagnetic device 422 may be aligned in a +Z axis direction or a -Z axis direction due to magnetic anisotropy. The ferromagnetic device 422 may include a first magnetic domain 423, which may be a region magnetized in the +Z axis direction. The ferromagnetic device 422 may include a second magnetic domain 424, which may be a region magnetized in the -Z axis direction. Additionally, the ferromagnetic device 422 may include a magnetic domain wall 425, which may be a boundary between the first magnetic domain 423 and the second magnetic domain 424. For example, a thickness of the magnetic domain wall 425 may be between several nm and several tens of nm, but is not limited thereto.

A current may be applied to the ferromagnetic device 422 by the magnetization control circuit (e.g., magnetization control circuit 450 of FIG. 4C and electronic device 1100). When the current is applied to the ferromagnetic device 422, the magnetic domain wall 425 of the ferromagnetic device 422 may move due to the spin-transfer torque (STT) phenomenon. The STT phenomenon is a phenomenon in which, when a spin direction of conduction electrons injected into a magnetic material (e.g., a ferromagnetic material) is not parallel to a magnetization direction of the magnetic material, the spin angular momentum of the conduction electrons is transferred to a magnetic moment of the magnetic material, thereby changing the magnetization direction of the magnetic material. By the STT phenomenon, the magnetic domain wall 425 may move in a direction of current applied to the ferromagnetic device 422 or in the opposite direction of the current.

The magnetization control circuit may induce a STT phenomenon by applying a current pulse greater than a certain threshold value to the ferromagnetic device 422. Since a ferromagnetic material may maintain its magnetization direction even in the absence of an external magnetic field, the magnetic domain wall 425 may be maintained as if even if no current is applied.

Referring to FIG. 4B, in a non-limiting example, the first chip 410 and the second chip 420 may be bonded by the interconnect component 430 such that a surface on which a superconducting quantum device of the first chip 410 is arranged and a surface on which the ferromagnetic device 422 of the second chip 420 is arranged face each other.

The ferromagnetic device 422 may be arranged to be spaced apart from the superconducting quantum device. For example, a distance between the ferromagnetic device 422 and the superconducting quantum device may be, but is not limited to, tens of nm to hundreds of nm.

In an example, the ferromagnetic device 422 may extend in an X axis direction between first and second superconducting layers of the superconducting quantum device. A length of the ferromagnetic device 422 in the X axis direction may be longer than a length of a loop L1 of the superconducting quantum device in the X axis direction.

In an example, the ferromagnetic device 422 may be arranged outside the loop L1 of the superconducting quantum device. For example, the ferromagnetic device 422 may be arranged outside the loop L1 in the +X axis direction or outside the loop L1 in the -X axis direction.

A current may be applied to the ferromagnetic device 422 in the +X axis direction or the -X axis direction. Accordingly, the magnetic domain wall 425 may move in the +X axis direction or the -X axis direction.

Depending on a location of the magnetic domain wall 425, the magnetic flux passing through the loop L1 may vary. For example, in FIG. 4B, if the magnetic domain wall 425 is located outside the loop L1 in the -X axis direction, the +Z axis direction magnetic flux of the ferromagnetic device 422 may pass through the loop L1. That is, a magnetic field in the +Z axis direction may be formed inside the loop L1. Alternatively, if the magnetic domain wall 425 is located at a center of the loop L1, the magnetic flux inside the loop L1 may be canceled. Alternatively, if the magnetic domain wall 425 is located outside the loop L1 in the +X axis direction, the magnetic flux of the ferromagnetic device 422 in the -Z axis direction may pass through the loop L1. That is, a magnetic field in the -Z direction may be formed inside the loop L1. If the magnetic flux passing through the loop L1 is changed, the resonant frequency of the superconducting quantum device may be changed.

Referring to FIGS. 4B and 4C, in a non-limiting example, when a first current pulse 441 in the +X axis direction (i.e., I_{bias} of FIG. 4C) is applied to the ferromagnetic device 422 from a magnetization control circuit 450, the magnetic domain wall 425 may move to the first position P1. For example, the first position P1 may be outside the loop L1 in the +X axis direction. Accordingly, a magnetic flux in the -Z axis direction may pass inside the loop L1, and the resonant frequency of the superconducting quantum device may be adjusted to a first resonant frequency F1.

If no current is applied after the first current pulse 441, the magnetic domain wall 425 may remain at the first position P1. Accordingly, the resonant frequency of the superconducting quantum device may be maintained at the first resonant frequency F1.

When a second current pulse 442 in the -X axis direction (i.e., I_{bias} of FIG. 4C) is applied to the ferromagnetic device 422 from the magnetization control circuit 450, the magnetic domain wall 425 may move to a second position P2. For example, the second position P2 may be outside the loop L1 in the -X axis direction. Accordingly, a magnetic flux in the +Z axis direction may pass inside the loop L1, and the resonant frequency of the superconducting quantum device may be adjusted to a second resonant frequency F2.

If no current is applied after the second current pulse 442, the magnetic domain wall 425 may remain at the second position P2. Accordingly, the resonant frequency of the superconducting quantum device may be maintained at the second resonant frequency F2.

Referring to FIG. 4C, profiles of the first and second current pulses 441 and 442 may be determined based on a distance and direction in which the magnetic domain wall 425 is to be moved.

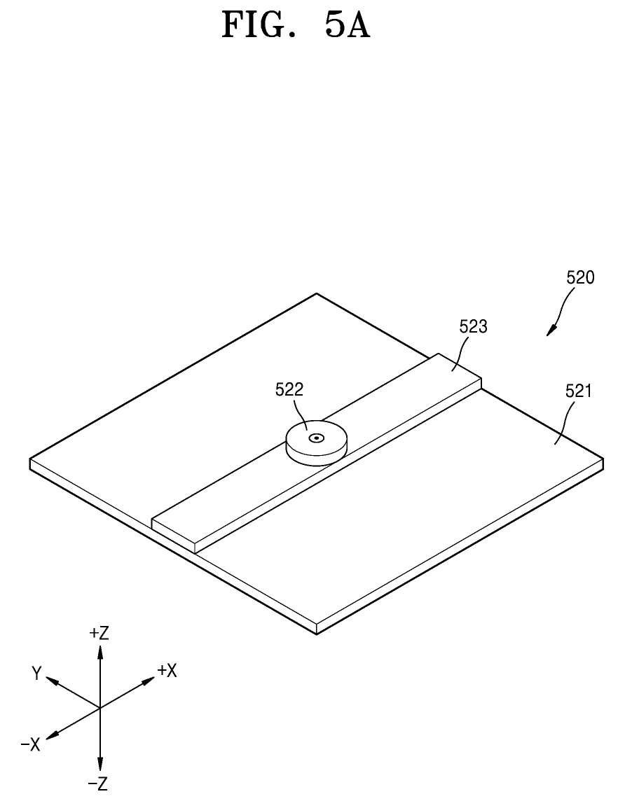

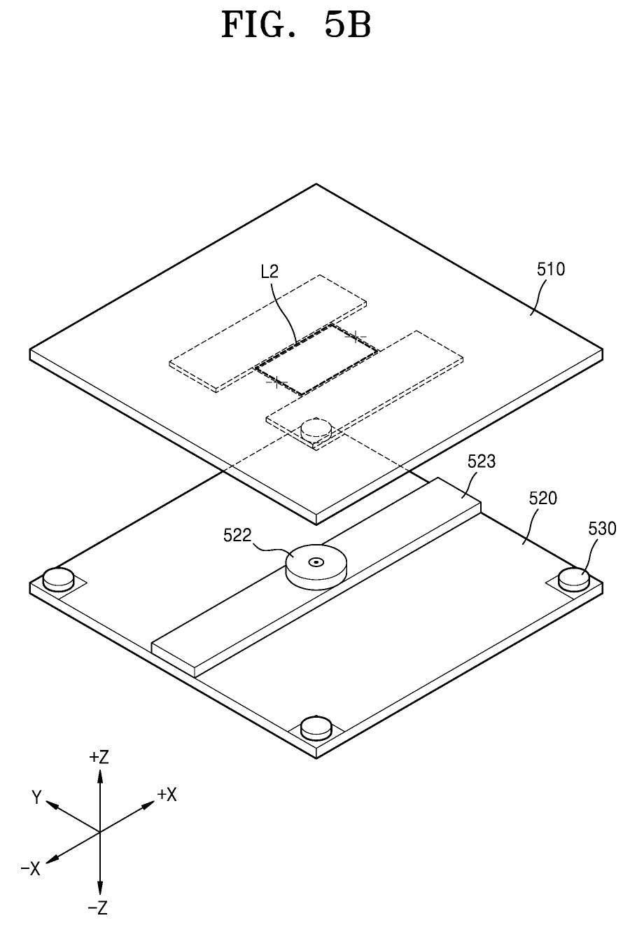

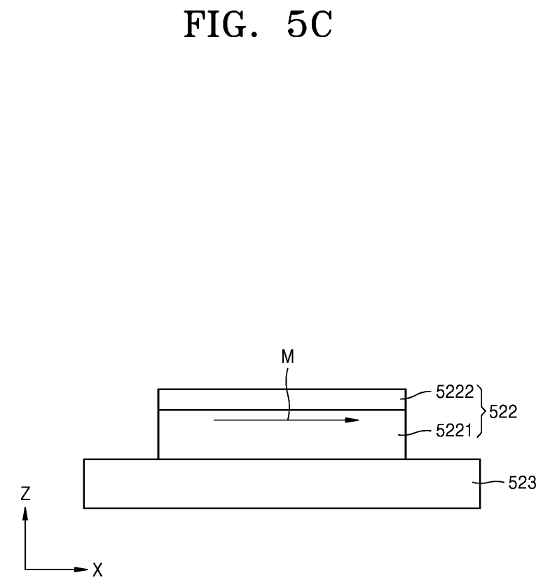

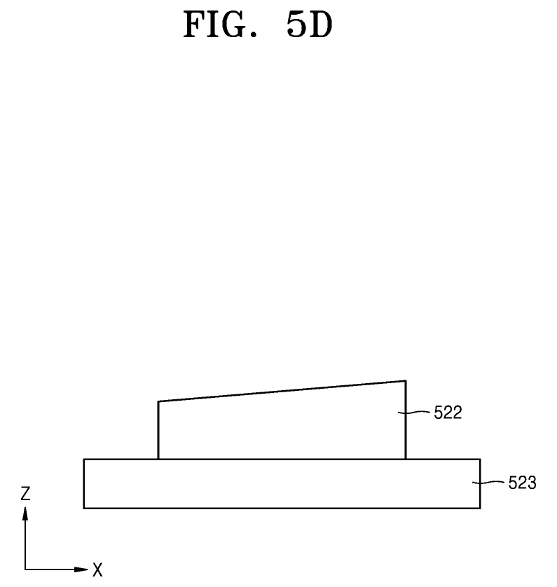

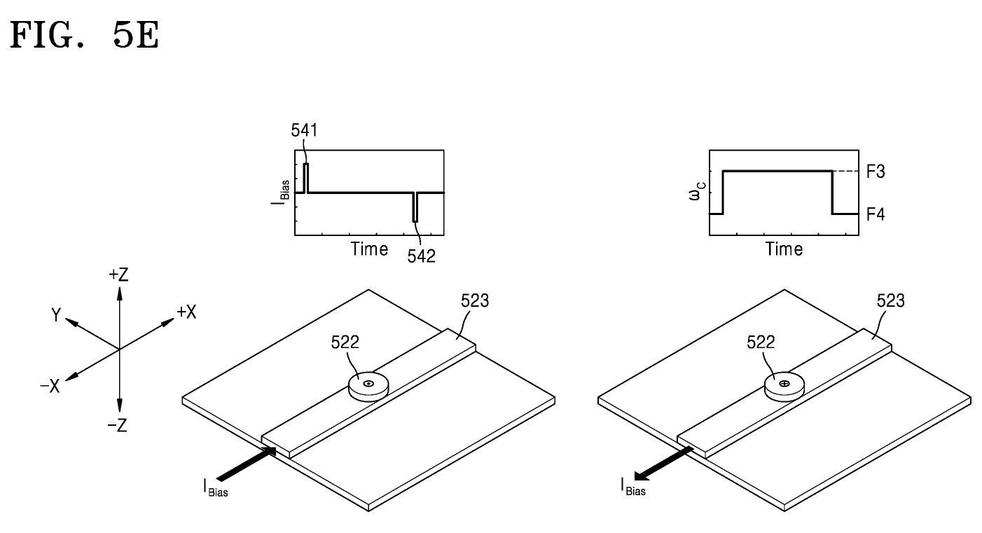

FIGS. 5A-5E illustrate an example superconducting quantum chip according to one or more embodiments.

The descriptions from among FIGS. 5A-5E may be the same and in some instances, repeated descriptions are omitted.

Referring to FIG. 5A, in a non-limiting example, the second chip 520 may include a substrate 521, a ferromagnetic device 522, and a wire 523.

The wire 523 may include a heavy metal material. For example, the heavy metal material may be a material exhibiting a significant spin-hall effect, such as Ta, Pt, Pd, W, Ru, etc., but is not limited thereto.

A current may be applied to the wire 523 by a magnetization control circuit (e.g., magnetization control circuit 450). When the current is applied to the wire 523, a magnetization direction of the ferromagnetic device 522 may be reversed due to a spin-orbit torque (SOT) phenomenon. The SOT phenomenon is a phenomenon in which, when a current greater than a critical value is applied to a heavy metal layer arranged adjacent to a ferromagnetic layer, the current provides a torque to the magnetization of the ferromagnetic layer, causing magnetization switching. By the SOT phenomenon, the magnetization direction of the ferromagnetic device 522 may be switched to the +Z axis direction or the -Z axis direction.

The magnetization control circuit may induce a SOT phenomenon by applying a current pulse greater than a certain threshold value to the wire 523. Since a ferromagnetic material may maintain its magnetization direction even in the absence of an external magnetic field, the magnetization direction of the ferromagnetic device 522 may be maintained even if no current is applied.

Referring to FIG. 5B, in a non-limiting example, the first chip 510 and the second chip 520 may be bonded to each other by an interconnect component 530 such that a surface of the first chip 510, on which a superconducting quantum device is arranged, and a surface of the second chip 520, on which the ferromagnetic device 522 is arranged, face each other.

In an example, the ferromagnetic device 522 may be arranged to face the inside of a loop L2 of the superconducting quantum device. For example, a center of the ferromagnetic device 522 and a center of the loop L2 of the superconducting quantum device may be located on a same axis.

In an example, the ferromagnetic device 522 may be arranged to face the outside of the loop L2 of the superconducting quantum device. For example, the ferromagnetic device 522 may be arranged outside the loop L2 in the +X axis direction or outside the loop L2 in the -X axis direction.

The ferromagnetic device 522 may have various shapes such as a cylinder, a cube, or a rectangular parallelepiped. A length of the ferromagnetic device 522 in the X axis direction may be tens of nm to several μm (e.g., about 50 nm to about 5 μm), but is not limited thereto.

The ferromagnetic device 522 may be arranged adjacent to the wire 523. For example, the ferromagnetic device 522 may be arranged directly on the wire 523 or with a space therebetween.

In an example, the wire 523 may be arranged between first and second superconducting layers of the superconducting quantum device and parallel to the first and second superconducting layers. For example, a width of the wire 523 may be between tens of nm and tens of μm, but is not limited thereto.

A current may be applied to the wire 523 in the +X axis direction or the -X axis direction. For example, in FIG. 5B, when a current is applied to the wire 523 in the +X axis direction, the magnetization direction of the ferromagnetic device 522 is aligned in the +Z axis direction, and a magnetic flux of the ferromagnetic device 522 in the +Z axis direction may pass through the loop L2. That is, a magnetic field in the +Z direction may be formed inside the loop L2. Alternatively, when a current is applied to the wire 523 in the -X axis direction, the magnetization direction of the ferromagnetic device 522 may be aligned in the -Z axis direction, and the magnetic flux of the ferromagnetic device 522 in the -Z axis direction may pass through the loop L2. That is, a magnetic field in the -Z direction may be formed inside the loop L2. If the magnetic flux passing through the loop L2 is changed, the resonant frequency of the superconducting quantum device may be changed.

In order for the magnetization direction of the ferromagnetic device 522 to be switched by the SOT phenomenon according to a direction of the current, the horizontal symmetry of the ferromagnetic device 522 should be broken. For this purpose, the ferromagnetic device 522 may have a shape that is configured to break the horizontal symmetry.

Referring to FIG. 5C, in non-limiting example, the ferromagnetic device 522 may include a ferromagnetic layer 5221 and an antiferromagnetic layer 5222. The ferromagnetic layer 5221 may be arranged on the wire 523, and the antiferromagnetic layer 5222 may be arranged on the ferromagnetic layer 5221. The antiferromagnetic layer 5222 may generate a local horizontal (X axis direction) magnetic field M in the ferromagnetic layer 5221, which may break the horizontal symmetry of the ferromagnetic device 522.

Referring to FIG. 5D, in a non-limiting example, when a vertical (Z axis direction) thickness of the ferromagnetic device 522 varies, the horizontal symmetry of the ferromagnetic device 522 may be broken. For example, in FIG. 5D, the shape of the ferromagnetic device 522 is illustrated as breaking the horizontal symmetry of the ferromagnetic device 522. However, other examples are not limited thereto.

Referring to FIG. 5E, in a non-limiting example, and to FIG. 5C, when a first current pulse 541 in the +X axis direction is applied to the wire 523 from the magnetization control circuit, the magnetization direction of the ferromagnetic device 522 may be aligned in the +Z axis direction. Accordingly, a magnetic flux in the +Z axis direction passes inside the loop L2, and the resonant frequency of the superconducting quantum device may be adjusted to a first resonant frequency F3.

If no current is applied after the first current pulse 541, the magnetization direction of the ferromagnetic device 522 may be maintained in the +Z axis direction. Accordingly, the resonant frequency of the superconducting quantum device may be maintained at the first resonant frequency F3.

When a second current pulse 542 in the -X axis direction is applied to the wire 523 from the magnetization control circuit, the magnetization direction of the ferromagnetic device 522 may be aligned in the -Z axis direction. Accordingly, a magnetic flux in the -Z axis direction passes inside the loop L2, and the resonant frequency of the superconducting quantum device may be adjusted to a second resonant frequency F4.

If no current is applied after the second current pulse 542, the magnetization direction of the ferromagnetic device 522 may be maintained in the -Z axis direction. Accordingly, the resonant frequency of the superconducting quantum device may be maintained at the second resonant frequency F4.

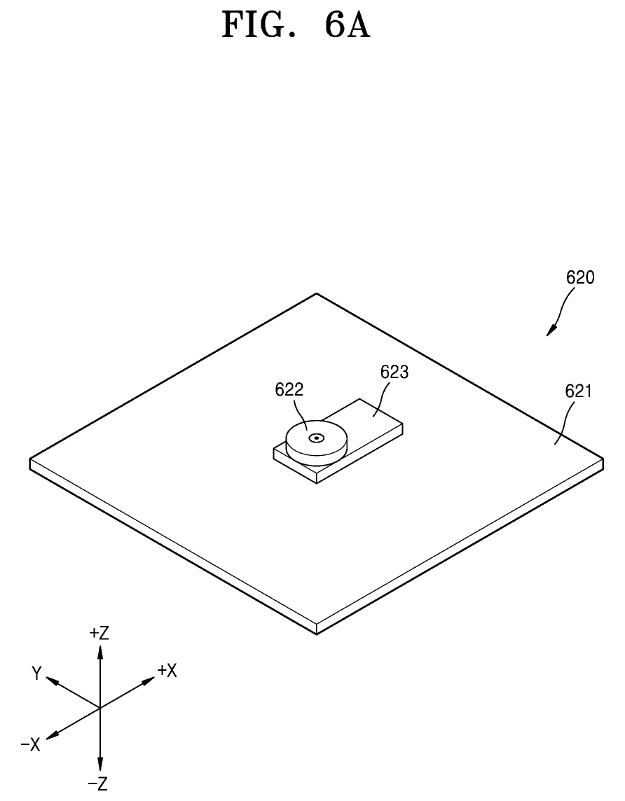

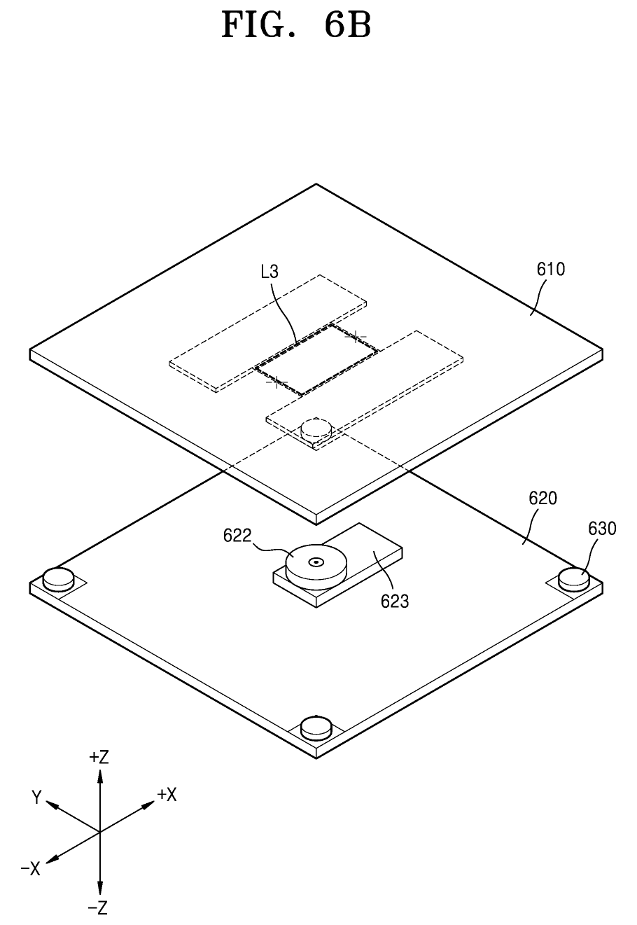

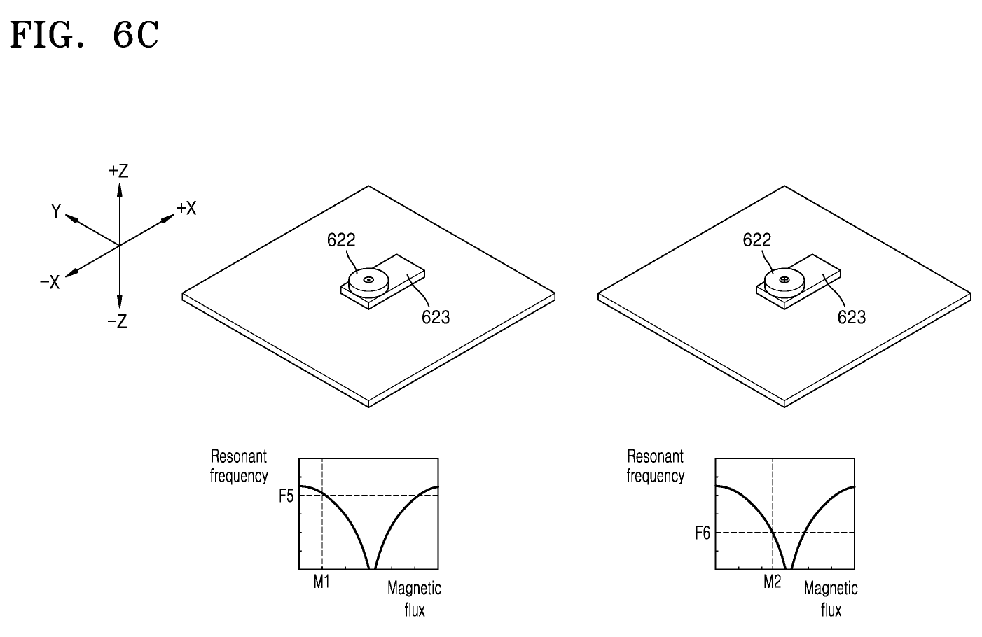

FIGS. 6A-6C illustrate an example superconducting quantum chip according to one or more embodiments.

Referring to FIG. 6A, in a non-limiting example, the second chip 620 may include a substrate 621, a ferromagnetic device 622, and a voltage gate 623.

A magnetization control circuit (e.g., magnetization control circuit 450) may apply a voltage to the ferromagnetic device 622 through the voltage gate 623. When the voltage is applied to the ferromagnetic device 622, a saturation flux density of the ferromagnetic device 622 may change. In ferromagnetic materials, the magnetic flux density increases with the strength of the magnetic field. However, once a certain level is reached, the magnetic flux density no longer increases no matter how much the magnetic field strength is increased. The flux density that reaches this limit is called a saturation flux density.

The saturation flux density of the ferromagnetic device 622 may vary depending on the strength of the voltage applied to the ferromagnetic device 622. For example, increasing the voltage may increase the saturation flux density, and decreasing the voltage may decrease the saturation flux density. Alternatively, the opposite may also occur.

The saturation flux density of the ferromagnetic device 622 may vary depending on a sign of the voltage applied to the ferromagnetic device 622. For example, when a positive voltage is applied, the saturation flux density may increase, and when a negative voltage is applied, the saturation flux density may decrease. Alternatively, the opposite may also happen.

The magnetization direction of the ferromagnetic device 622 may change depending on the sign of the voltage applied to the ferromagnetic device 622. For example, when a positive voltage is applied, the magnetization direction of the ferromagnetic device 622 may be aligned in the +Z axis direction, and when a negative voltage is applied, the magnetization direction of the ferromagnetic device 622 may be aligned in the -Z axis direction. Alternatively, the opposite may also occur.

With respect to FIGS. 6B and 6C being described below, descriptions of elements that were already described with respect to FIG. 6A may be omitted.

Referring to FIG. 6B, in a non-limiting example, the first chip 610 and the second chip 620 may be bonded by an interconnect component 630 such that a surface of the first chip 610, on which the superconducting quantum device is arranged, and a surface of the second chip 620, on which the ferromagnetic device 622 is arranged, face each other.

In an example, the ferromagnetic device 622 may be arranged to face the inside of a loop L3 of the superconducting quantum device. For example, a center of the ferromagnetic device 622 and a center of the loop L3 of the superconducting quantum device may be located on a same axis.

In an example, the ferromagnetic device 622 may be arranged to face the outside of the loop L3 of the superconducting quantum device. For example, the ferromagnetic device 622 may be arranged outside the loop L3 in the +X axis direction or outside the loop L3 in the -X axis direction.

A diameter of the ferromagnetic device 622 may be tens of nm to several μm (e.g., about 50 nm to about 5 μm). The ferromagnetic device 622 may have various shapes such as a cylinder, a cube, or a rectangular parallelepiped.

The ferromagnetic device 622 may be arranged on a voltage gate 623. The ferromagnetic device 622 may be electrically connected to the voltage gate 623.

In an example, a positive or negative voltage may be applied to the voltage gate 623. For example, in FIG. 6B, when a positive voltage is applied to the voltage gate 623, the magnetization direction of the ferromagnetic device 622 may be aligned in the +Z axis direction. By increasing the positive voltage of the voltage gate 623, the saturation flux density of the ferromagnetic device 622 may increase. For example, when a negative voltage is applied to the voltage gate 623, the magnetization direction of the ferromagnetic device 622 may be aligned in the -Z axis direction. By increasing the strength of the negative voltage of the voltage gate 623, the saturation flux density of the ferromagnetic device 622 may increase. Depending on a sign and magnitude of the voltage of the voltage gate 623, a direction and magnitude of the magnetic flux passing through the loop L3 may be changed, and accordingly, the resonant frequency of the superconducting quantum device may be changed.

Referring to FIG. 6C, in a non-limiting example, and further referring to FIG. 6B, when a positive voltage is applied to the voltage gate 623 from the magnetization control circuit, the magnetization direction of the ferromagnetic device 622 may be aligned in the +Z axis direction. Additionally, the magnetic flux density of the ferromagnetic device 622 may be determined depending on the strength of the positive voltage. Accordingly, a first magnetic flux M1 in the +Z axis direction may pass inside the loop L3, and the resonant frequency of the superconducting quantum device may be adjusted to a first resonant frequency F5.

When a negative voltage is applied to the voltage gate 623 from the magnetization control circuit, the magnetization direction of the ferromagnetic device 622 may be aligned in the -Z axis direction. Additionally, the magnetic flux density of the ferromagnetic device 622 may be determined depending on the strength of the negative voltage. Accordingly, a second magnetic flux M2 in the -Z axis direction may pass inside the loop L3, and the resonant frequency of the superconducting quantum device may be adjusted to a second resonant frequency F6.

In an example, the superconducting quantum device may be a qubit or a qubit coupler. The description with reference to FIGS. 4A-6C may be utilized for various operations of superconducting quantum devices, such as setting a resonant frequency of a qubit/qubit coupler to a certain resonant frequency, setting an energy level of the qubit/qubit coupler, changing the resonant frequency of the qubit/qubit coupler, coupling qubits, or decoupling qubits.

For example, when a superconducting quantum device is a qubit, the resonant frequency of the qubit may be tuned to the first resonant frequency F1, F3, or F5 or the second resonant frequency F2, F4, or F6 by controlling the magnetic field of the ferromagnetic device.

For example, when a superconducting quantum device is a qubit coupler, the resonant frequency of the qubit coupler may be tuned to the first resonant frequency F1, F3, or F5 by controlling the magnetic field of the ferromagnetic device. As long as the resonant frequency of the qubit coupler is maintained at the first resonant frequency F1, F3, or F5, the qubits connected to the qubit coupler may maintain a coupled state. Alternatively, by controlling the magnetic field of the ferromagnetic device, the resonant frequency of the qubit coupler may be tuned to a second resonant frequency F2, F4, or F6. As long as the resonant frequency of the qubit coupler is maintained at the second resonant frequency F2, F4, or F6, the qubits connected to the qubit coupler may remain in a decoupled state.

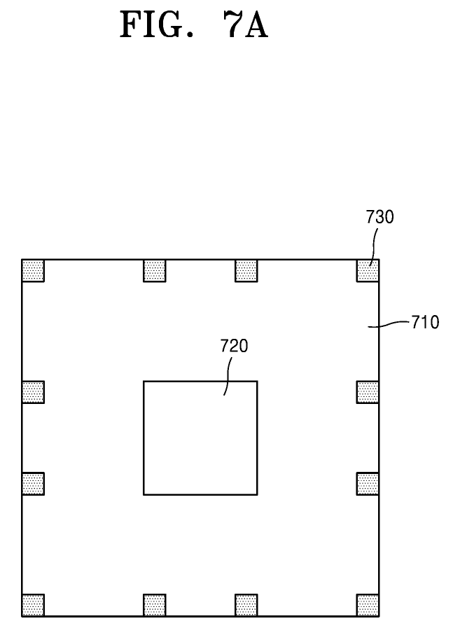

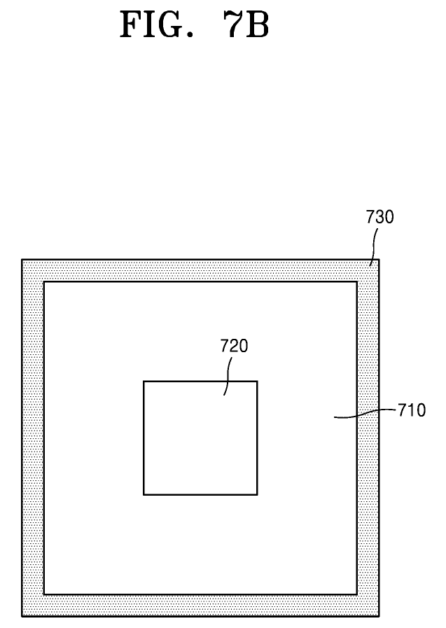

FIG. 7A illustrates an example interconnect component according to one or more embodiments.

Referring to FIG. 7A, in a non-limiting example, an interconnect component 730 may be arranged to surround a superconducting quantum device 720 (or ferromagnetic device) of the first chip 710 (or second chip).A plurality of interconnect components 730 may be spaced apart from one another and arranged to surround the superconducting quantum device 720 (or ferromagnetic device) of the first chip 710 (or second chip).

FIG. 7B illustrates an example interconnect component according to one or more embodiments.

Referring to FIG. 7B, in a non-limiting example, the interconnect component 730 may be positioned to completely surround the superconducting quantum device 720 (or ferromagnetic device) between the first chip 710 and the second chip.

In an example, substrates of the first chip 710 and/or the second chip may include a magnetic shielding material. For example, the substrates of the first chip 710 and/or the second chip may include, but are not limited to, ceramic (e.g., ferrite). Since the substrates of the first chip 710 and the second chip include a magnetic shielding material, the influence of the magnetic field of the ferromagnetic device on an external element may be minimized.

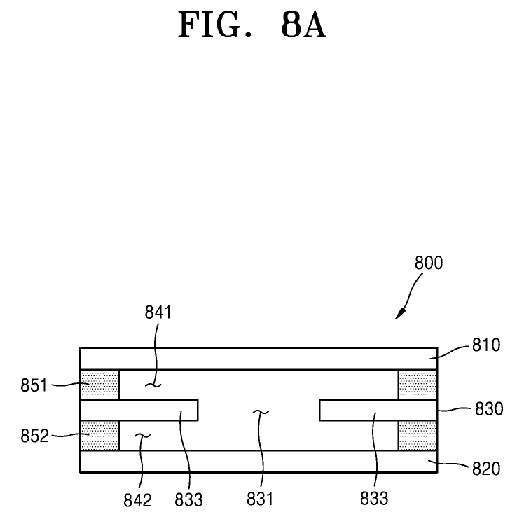

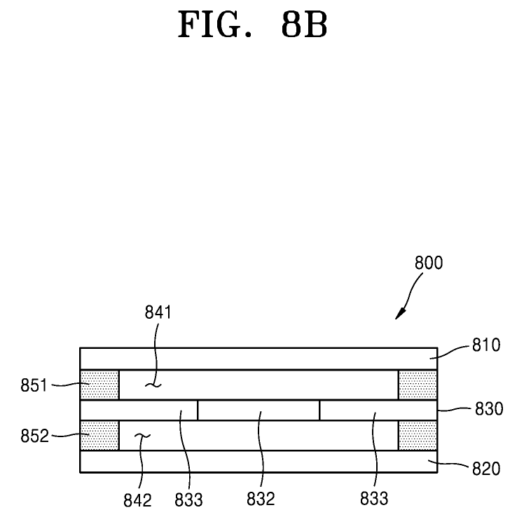

FIGS. 8A and 8B illustrate an example superconducting quantum chip according to one or more embodiments.

T

Referring to FIG. 8A, in a non-limiting example, a superconducting quantum chip 800 may include a first chip 810, a second chip 820, and an intermediate layer 830. The first chip 810 may include at least one superconducting quantum device. The second chip 820 may include at least one ferromagnetic device (e.g., ferromagnetic device 422).

The intermediate layer 830 may be bonded between the first chip 810 and the second chip 820 such that a first gap 841 is formed between the first chip 810 and the intermediate layer 830 and a second gap 842 is formed between the second chip 820 and the intermediate layer 830. The first chip 810 and the intermediate layer 830 may be physically connected to each other by a first interconnect component 851. Additionally, the second chip 820 and the intermediate layer 830 may be physically connected to each other by a second interconnect component 852.

In an example, the intermediate layer 830 may be a magnetic shielding layer including a magnetic shielding material. The intermediate layer 830 may include an empty space 831. The empty space 831 may be a hole or a gap. In the intermediate layer 830, the empty space 831 may correspond to a first region 831 of the intermediate layer 830, and the remainder thereof may correspond to a second region 833 of the intermediate layer 830.

With respect to FIG. 8B being described below, descriptions of elements that were already described with respect to FIG. 8A may be omitted.

Referring to FIG. 8B, in a non-limiting example, the intermediate layer 830 may be an insulating layer including an insulating material. The intermediate layer 830 may include a first region 832 that is not coated with a magnetic shielding material. Additionally, the intermediate layer 830 may include the second region 833, which is a remaining region coated with a magnetic shielding material.

As the intermediate layer 830 includes the first region 831 that does not perform magnetic shielding, the resonant frequency of the superconducting quantum device of the first chip 810 may be controlled by the magnetic field of the ferromagnetic device of the second chip 820.

As the intermediate layer 830 includes the second region 833 that performs magnetic shielding, the influence of the magnetic field of the ferromagnetic device of the second chip 820 on an external element may be minimized.

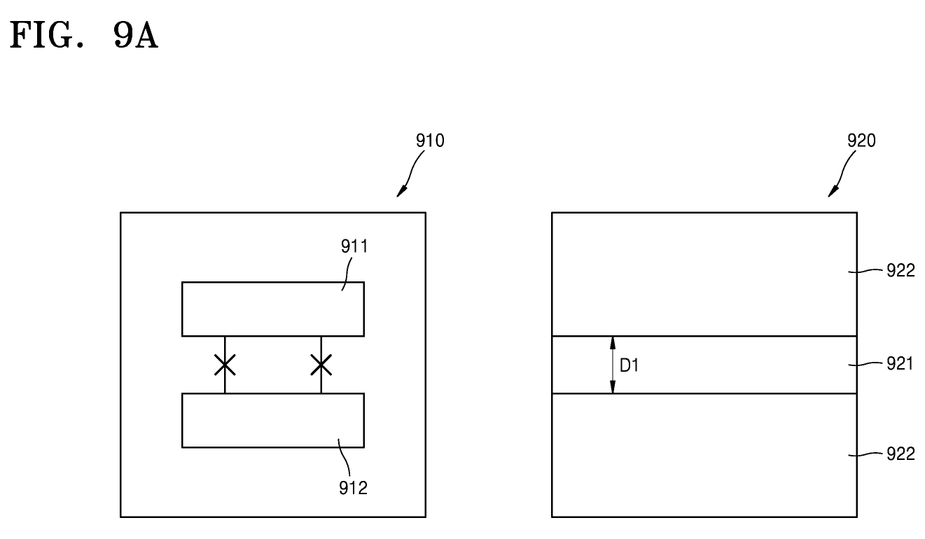

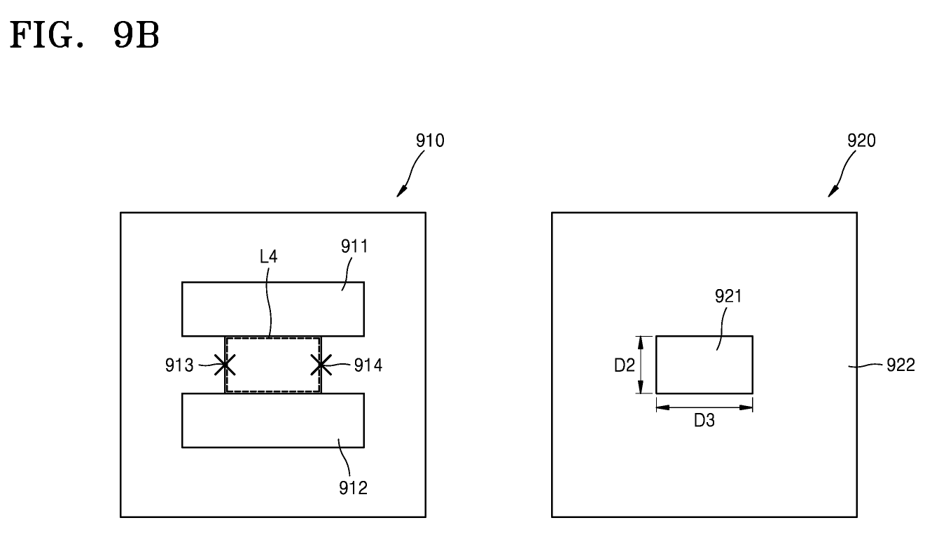

FIGS. 9A and 9B illustrate an example intermediate layer according to one or more embodiments.

Referring to FIG. 9A, in an embodiment, in a non-limiting example, the intermediate layer 920 may include a first region 921 configured not to perform magnetic shielding and a second region 922 configured to perform magnetic shielding.

In an example, the first region 921 may be arranged between first and second superconducting layers 911 and 912 of the first chip 910 and parallel to the first and second superconducting layers 911 and 912.

In an embodiment, a width D1 of the first region 921 may be less than a spacing between the first and second superconducting layers 911 and 912. For example, the spacing between the first and second superconducting layers 911 and 912 may be 100 μm or more, and the width D1 of the first region 921 may be less than 100 μm.

As the first region 921 is positioned between the first and second superconducting layers 911 and 912, and the width D1 of the first region 921 is less than the spacing between the first and second superconducting layers 911 and 912, the first and second superconducting layers 911 and 912 may be magnetically shielded from a ferromagnetic device of a second chip by the second region 922. Accordingly, the influence of a magnetic field of the ferromagnetic device of the second chip on the first and second superconducting layers 911 and 912 may be minimized. In addition, the Meissner effect may be prevented from occurring in the first and second superconducting layers 911 and 912 by the magnetic field of the ferromagnetic device of the second chip.

Referring to FIG. 9B, in a non-limiting example, the first region 921 may be arranged to face a loop L4 of the first chip 910. For example, a center of the first region 921 and a center of the loop L4 may be located on a same axis.

In an example, a width D2 of the first region 921 may be smaller than the spacing between the first and second superconducting layers 911 and 912. Additionally, a length D3 of the first region 921 may be less than a spacing between first and second Josephson junctions 913 and 914.

The resonant frequency of a superconducting quantum device may be determined based on a magnetic flux passing through the loop L4. The magnetic field of the ferromagnetic device of the second chip may be applied to the loop L4 by the first region 921, and the influence of the magnetic field of the ferromagnetic device on the first and second superconducting layers 911 and 912 and an external element may be minimized by the second region 922.

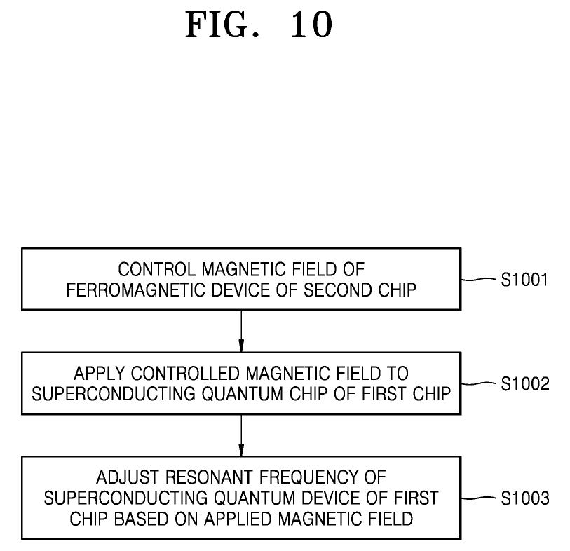

FIG. 10 illustrate an example method of operating a superconducting quantum chip according to one or more embodiments.

Referring to FIG. 10, in a non-limiting example, a superconducting quantum chip may include a first chip (e.g., first chip 110 of FIG. 1) including a superconducting quantum device (e.g., superconducting quantum device 220 of FIG. 2) and a second chip (e.g., second chip 120 of FIG. 1) which is bonded to the first chip with a gap between the first chip and the second chip and includes a ferromagnetic device (e.g., ferromagnetic device 422 of FIG. 4A).

In an example, in operation S1001, a magnetic field of the ferromagnetic device of the second chip may be controlled.

The magnetic field of the ferromagnetic device may be controlled by a magnetization control circuit (e.g., magnetization control circuit 450). In an example, the magnetization control circuit may control the magnetic field of the ferromagnetic device by controlling a position of a magnetic domain wall of the ferromagnetic device by applying a current pulse to the ferromagnetic device. In an example, the magnetization control circuit may control the magnetic field of the ferromagnetic device by controlling a magnetization direction of the ferromagnetic device by applying a current pulse to a wire adjacent to the ferromagnetic device. In an example, the magnetization control circuit may control the magnetic field of the ferromagnetic device by controlling the magnetization direction and a strength of the magnetic field of the ferromagnetic device by applying a voltage to the ferromagnetic device through a voltage gate.

In an example, in operation S1002, a controlled magnetic field may be applied to the superconducting quantum device of the first chip.

A surface on which the superconducting quantum device of the first chip is arranged and a surface on which the ferromagnetic device of the second chip is arranged may face each other. Accordingly, a controlled magnetic field from the ferromagnetic device may be applied to the superconducting quantum device of the first chip.

In an example, in operation S1003, a resonant frequency of the superconducting quantum device of the first chip may be adjusted based on the applied magnetic field.

FIG. 11 illustrates an example electronic device according to one or more embodiments.

Referring to FIG. 11, in a non-limiting example, an electronic device 1100 may control a superconducting quantum circuit system, and the electronic device 1100 may include a processor 1110 and a memory 1120. The processor 1110 may be one or more processors or processing elements. In an example, the processor 1110 may control a superconducting quantum device (e.g., superconducting quantum device 220 of FIG. 2) as or through, for example, a magnetization control circuit (e.g., magnetization control circuit 450).

The processor 1110 may be configured to execute programs or applications to configure the processor 1110 to control the electronic apparatus 1100 to perform one or more or all operations and/or methods involving the control of a superconducting quantum device including a magnetization control circuit, and may include any one or a combination of two or more of, for example, a central processing unit (CPU), a graphic processing unit (GPU), a neural processing unit (NPU) and tensor processing units (TPUs), but is not limited to the above-described examples.

The memory 1120 may include computer-readable instructions. The processor 1110 may be configured to execute computer-readable instructions, such as those stored in the memory 1120, and through execution of the computer-readable instructions, the processor 1110 is configured to perform one or more, or any combination, of the operations and/or methods described herein. The memory 1120 may be a volatile or nonvolatile memory.

The resonant frequency of the superconducting quantum device may be determined based on the magnetic field of the ferromagnetic device. In an example, when the magnetic field of the ferromagnetic device is changed, the resonant frequency of the superconducting quantum device may be changed. Additionally, if the magnetic field of the ferromagnetic device is maintained, the resonant frequency of the superconducting quantum device may be maintained.

Typical methods of continuously applying a current to a qubit to maintain a resonant frequency of the qubit is inefficient because the resonant frequency is not maintained if no current is applied. Additionally, the reliability of a measured resonant frequency may be reduced due to noise resulting from the continuous supply of current. Additionally, a separate low-temperature electronic component (e.g. a low-temperature DC line) is required to continuously supply current.

On the other hand, in an example, a ferromagnetic device may maintain a magnetized state even when no current is applied. Therefore, by applying a current pulse to the ferromagnetic device, the resonant frequency of a superconducting quantum device may be controlled. Additionally, the resonant frequency of the superconducting quantum device may be maintained without current. Additionally, it does not require a separate low-temperature electronic component to continuously supply current.

In addition, in an example, since a first chip including a superconducting quantum device and a second chip including a ferromagnetic device are separated in a superconducting quantum chip, the design and manufacturing of the first chip and the second chip may be efficiently performed. In addition, since the sizes of the first chip and the second chip may be reduced, the area efficiency of the superconducting quantum chip may be improved.

The superconducting quantum devices, electronic apparatuses, processors, memories, qubits, superconducting quantum chip 100, first chip 110, second chip 120, interconnect component 130, pad 131, bump 132, first chip 200, second chip 220, first and second Josephson junctions 223 and 224, first chip 300, substrate 310, superconducting quantum device 320, first super conducting layer 321, second superconducting layer 322, ferromagnetic link 333, second chip 420, substrate 421, ferromagnetic device 422, magnetic domain wall 425, magnetization control circuit 450, second chip 520, substrate 521, ferromagnetic device 522, wire 523, ferromagnetic layer 5221, antiferromagnetic layer 5222, second chip 620, substrate 621, ferromagnetic device 622, voltage gate 623, first chip 710, superconducting quantum chip 800, first chip 810, second chip 820, intermediate layer 830, first interconnect component 851, second interconnect component 852, first chip 910, and first and second superconducting layers 911 and 912 described herein and disclosed herein described with respect to FIGS. 1-11 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term "processor" or "computer" may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-11 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD- Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks , and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A superconducting quantum chip, comprising:
a first chip comprising a superconducting quantum device having a controllable resonant frequency;
a second chip bonded to the first chip with a gap defined between the first chip and the second chip; and
a ferromagnetic device provided on the second chip, the ferromagnetic device being configured to apply a magnetic field to the superconducting quantum device to control a resonant frequency of the superconducting quantum device.

2. The superconducting quantum chip of claim 1, wherein the superconducting quantum device is arranged on a first surface of the first chip,
wherein the ferromagnetic device is arranged on a second surface of the second chip, and
wherein the first surface and the second surface are configured to face each other.

3. The superconducting quantum chip of claim 1, wherein the first chip further comprises:
a first substrate on which the superconducting quantum device is arranged, and
wherein the first substrate comprise a magnetic shielding material.

4. The superconducting quantum chip of claim 1, wherein the second chip further comprises:
a second substrate on which the ferromagnetic device is arranged, and
wherein the second substrate comprises a magnetic shielding material.

5. The superconducting quantum chip of claim 1, further comprising:
an interconnect component configured to physically connect the first chip and the second chip to each to form the gap between the first chip and the second chip,
wherein the interconnect component comprises a superconducting material.

6. The superconducting quantum chip of claim 1, wherein the ferromagnetic device comprises a magnetic domain wall,
wherein the superconducting quantum device is configured to have a resonant frequency that changes with a position of the magnetic domain wall, and
wherein the position of the magnetic domain wall is determined based on a current flowing through the ferromagnetic device.

7. The superconducting quantum chip of claim 1, wherein the second chip comprises a wire arranged adjacent to the ferromagnetic device,
wherein the superconducting quantum device is configured to have a resonant frequency that changes depending on a magnetization direction of a ferromagnetic device, and
wherein the magnetization direction is determined based on a current flowing through the wire.

8. The superconducting quantum chip of claim 1, wherein the second chip comprises a voltage gate connected to the ferromagnetic device, and
wherein the superconducting quantum device is configured to have a resonant frequency that changes depending on a magnetization direction of the ferromagnetic device, and
wherein the magnetization direction is determined based on a voltage applied through the voltage gate.

9. The superconducting quantum chip of claim 1, wherein the second chip further comprises a magnetization control circuit configured to control a magnetization of the ferromagnetic device.

10. The superconducting quantum chip of claim 1, further comprising:
an intermediate layer provided between the first chip and the second chip,
wherein the intermediate layer comprises a magnetic shielding material, and
wherein the intermediate layer is bonded to the first chip and the second chip to form a first gap with respect to the first chip and a second gap with respect to the second chip.

11. The superconducting quantum chip of claim 10, wherein the intermediate layer comprises:
a first region in which a magnetic field generated by the ferromagnetic device is not blocked; and
a second region in which the magnetic field generated by the ferromagnetic device is blocked.

12. The superconducting quantum chip of claim 11, wherein the first region of the intermediate layer does not include the magnetic shielding material, and
wherein the second region of the intermediate layer comprises the magnetic shielding material.

13. The superconducting quantum chip of claim 11, wherein the intermediate layer comprises an insulating layer,
wherein the insulating layer is not coated with the magnetic shielding material in the first region, and
wherein the insulating layer is coated with the magnetic shielding material in the second region.

14. The superconducting quantum chip of claim 11, wherein the intermediate layer comprises:
a magnetic shielding layer, the magnetic shielding layer having a hole defined therein,
wherein the first region is defined by the hole, and
wherein the second region comprises a remaining region of the magnetic shielding layer.

15. The superconducting quantum chip of claim 11, wherein the superconducting quantum device comprises a loop formed by a first superconducting layer, a second superconducting layer, a first Josephson junction, and a second Josephson junction, and
wherein the first region faces the loop.

16. The superconducting quantum chip of claim 15, wherein a width of the first region is less than 100 μm.

17. The superconducting quantum chip of claim 10, further comprising:
a first interconnect component configured to physically connect the first chip to the intermediate layer such that the first gap is formed between the first chip and the intermediate layer; and
a second interconnect component configured to physically connect the second chip to the intermediate layer such that the second gap is formed between the second chip and the intermediate layer.

18. A method, the method comprising:
controlling a magnetic field of a ferromagnetic device of a second chip of a superconducting quantum chip, the superconducting quantum chip comprising a first chip including a superconducting quantum device, the second chip, the second chip being bonded to the first chip and having a gap defined between the first chip and the second chip, and a ferromagnetic device;
applying the controlled magnetic field to the superconducting quantum device of the first chip; and
controlling a resonant frequency of the superconducting quantum device of the first chip based on the applied magnetic field.

19. An electronic device, comprising:
a ferromagnetic device formed on a second chip, the second chip being bonded to a first chip, the ferromagnetic device being configured to apply a magnetic field to a superconducting quantum device of the first chip to control a resonant frequency of the superconducting quantum device;
a processor configured to execute instructions; and
a memory storing the instructions, wherein execution of the instructions configures the processor to:
control a magnetization of the ferromagnetic device by applying a current pulse to the ferromagnetic device to change a location of a magnetic domain wall within the ferromagnetic device.

20. The electronic device of claim 19, wherein the superconducting quantum device comprises:
first and second Josephson junctions; and
first and second superconducting layers, the first and second superconducting layers and the first and second Josephson junctions being configured to form a loop, and
wherein the location of magnetic domain wall changes an amount of magnetic flux passing through the loop to control the resonant frequency of the superconducting quantum device.
